(19) United States
(12) Patent Application Publication
(10) Pub. No.: US 2025/0022312 A1
(43) Pub. Date: Jan. 16, 2025

(54) Identification of Facial Expression of Head-Mountable Display Wearer

(71) Applicant: Hewlett-Packard Development Company, L.P., Spring, TX (US)

(72) Inventors: Paul Howard Mazurkiewicz, Fort Collins, CO (US); Joseph Nouri, Fort Collins, CO (US); Mark Lessman, Fort Collins, CO (US)

(21) Appl. No.: 18/577,079

(22) PCT Filed: Jul. 16, 2021
(86) PCT No.: PCT/US2021/041937

§ 371 Date: Jan. 5, 2024

(51) Int. Cl. G06V 40/16; G01B 7/16; G01R 33/07; G02B 27/00; G02B 27/01

(52) U.S. Cl. CPC G06V 40/176; G01B 7/16; G01R 33/07; G02B 27/0093; G02B 27/017

(57) ABSTRACT

Facial movement of a wearer of a head-mountable display (HMD) is detected by detecting movement of a gasket of the HMD positioned against a face of the wearer using resistive or magnetic sensors within the gasket. A facial expression of the wearer is identified based on the detected facial movement.

### BACKGROUND

Extended reality (XR) technologies include virtual reality (VR), augmented reality (AR), and mixed reality (MR) technologies, and quite literally extend the reality that users experience. XR technologies may employ head-mountable displays (HMDs). An HMD is a display device that can be worn on the head. In VR technologies, the HMD wearer is immersed in an entirely virtual world, whereas in AR technologies, the HMD wearer's direct or indirect view of the physical, real-world environment is augmented. In MR, or hybrid reality, technologies, the HMD wearer experiences the merging of real and virtual worlds.

### BRIEF DESCRIPTION OF THE DRAWINGS

FIGS. 1A and 1B are perspective and front view diagrams, respectively, of an example head-mountable display (HMD) that can be used in an extended reality (XR) environment.

FIGS. 2A and 2B are front view and perspective diagrams, respectively, of different examples of an HMD gasket having resistive or magnetic sensors.

FIGS. 3A and 3B are diagrams of example HMD gasket magnetic and resistive sensors, respectively.

FIGS. 4A and 4B are diagrams of example facial expressions that can be identified using HMD gasket resistive or magnetic sensors.

FIG. 5 is a diagram of an example process for identifying a facial expression of an HMD wearer using HMD gasket resistive or magnetic sensors.

FIG. 6 is a diagram of how an example HMD gasket resistive or magnetic sensor can be used to determine proper HMD fit by a wearer.

FIG. 7 is a diagram of an example process for determining proper HMD fit by a wearer using HMD gasket resistive or magnetic sensors.

FIG. 8 is a diagram of how an example HMD gasket resistive or magnetic sensor can be used to determine excessive HMD gasket wear.

FIG. 9 is a diagram of an example process for determining excessive HMD gasket wear using HMD gasket resistive or magnetic sensors.

FIG. 10 is a diagram of an example non-transitory computer-readable data storage medium.

FIG. 11 is a flowchart of an example method.

FIG. 12 is a block diagram of an example HMD.

### DETAILED DESCRIPTION

As noted in the background, a head-mountable display (HMD) can be employed as an extended reality (XR) technology to extend the reality experienced by the HMD's wearer. An HMD can include one or multiple small display panels in front of the wearer's eyes, as well as various sensors to detect or sense the wearer and/or the wearer's environment. Images on the display panels convincingly immerse the wearer within an XR environment, be it a virtual reality (VR), augmented reality (AR), a mixed reality (MR), or another type of XR.

An HMD can include one or multiple cameras, which are image-capturing devices that capture still or motion images. For example, one camera of an HMD may be employed to capture images of the wearer's lower face, including the mouth. Two other cameras of the HMD may be each be employed to capture images of a respective eye of the HMD wearer and a portion of the wearer's face surrounding the eye.

In some XR applications, the facial expression exhibited by the wearer of an HMD may be identified. The facial expression may be identified so that an avatar representing the wearer can be rendered to have the same facial expression. The rendered avatar can then be displayed within the XR environment, such as on the display panels of the HMDs worn by other participants of the XR application. The facial expression of an HMD wearer may be identified for other reasons as well. For example, biometric inference processing may be performed on the basis of the identified facial expression, such as to deduce facial cues and the mood or emotion of the wearer.

The facial expression of an HMD wearer may be identified based on the images captured by the HMD's cameras. The wearer's facial expression may also be identified using other sensors. For example, facial electromyographic sensors (fEMG) sensors may be employed. fEMG sensors output signals that measure facial muscle activity by detecting and amplifying small electrical impulses that muscle fibers generate when they contract.

Techniques described herein, by comparison, employ resistive or magnetic sensors within the gasket of an HMD for identifying the facial expression of the HMD wearer. The gasket is the portion of the HMD that is positioned against the wearer's face, surrounding the eyes of the wearer and abutting the wearer's nose. The resistive or magnetic sensors specifically detect movement of the gasket resulting from facial movement of the wearer when exhibiting a facial expression. The wearer's facial expression can thus be identified based on the sensor values received from the sensors.

In the case of resistive sensors, the sensors may be resistive strain gauge sensors. Such strain gauge sensors measure physical strain imparted on the gasket, which causes physical stress within the gasket, as the wearer is exhibiting a facial expression, and thus as the wearer's facial movement is correspondingly causing gasket movement. In the case of magnetic sensors, the sensors may be magnetic Hall effect sensors. Such Hall effect sensors measure physical displacement of the gasket as the wearer is exhibiting a facial expression, and thus similarly as the wearer's facial movement is correspondingly causing gasket movement.

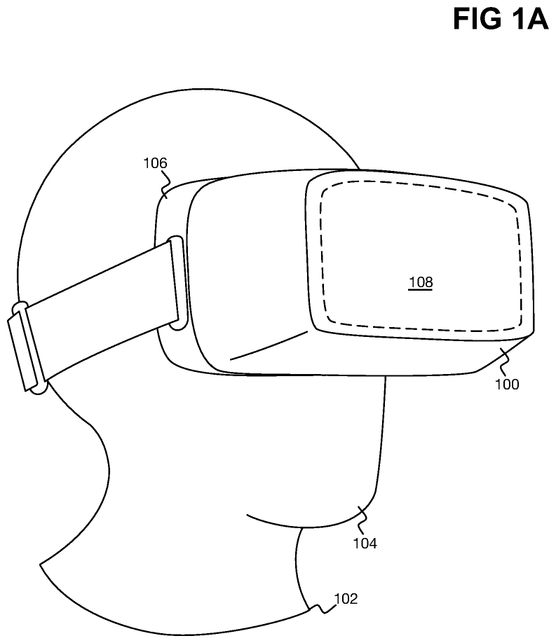

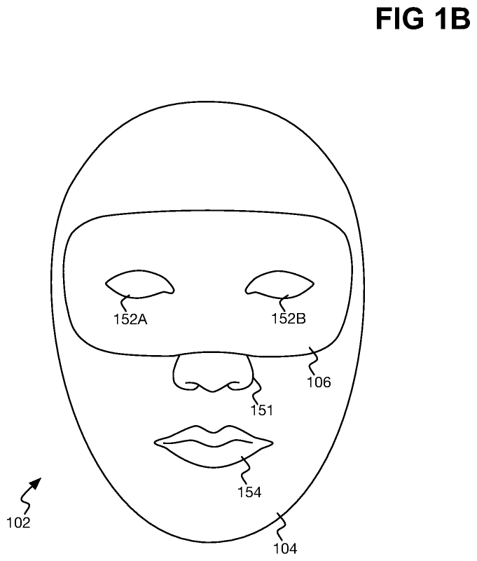

FIGS. 1A and 1B show perspective and front view diagrams of an example HMD 100 worn by a wearer 102 and positioned against the face 104 of the wearer 102. The HMD 100 includes a gasket 106 at one end of the HMD 100 that is positionable against the wearer 102's face 104 above the nose 151 and around the eyes 152A and 152B of the wearer 102 (per FIG. 1B), which are collectively referred to as the wearer 102's eyes 152. The gasket 106 may be fabricated from a soft flexible material, such as rubberized foam, that can deform in correspondence with contours of the wearer 102's face 104 to block ambient light from entering the interior of the HMD 100 at the interface between the gasket 106 and the face 104 of the wearer 102. The gasket 106 further promotes wearer 102 comfort in usage of the HMD 100, since the remainder of the HMD 100 may be fabricated from a rigid material such as plastic and/or metal.

The HMD 100 can include a display panel 108 inside the other end of the HMD 100 that is positionable incident to the eyes 152 of the wearer 102. The display panel 108 may in actuality include a right display panel incident to and viewable by the wearer 102's right eye 152A, and a left display panel incident to and viewable by the wearer's 102 left eye 152B. By suitably displaying images on the display panel 108, the HMD 100 can immerse the wearer 102 within an XR.

The HMD 100 may include other components in addition to those depicted in FIGS. 1A and 1B. For example, the HMD 100 may include eye cameras and/or a mouth camera. Such cameras can capture images of different portions of the face 104 of the wearer 102 of the HMD 100. The eye cameras may capture images of facial portions including and around respective eyes 152 of the wearer 102, whereas the mouth camera may capture images of a lower facial portion including and around the mouth 154 of the wearer 102. The HMD 100 can also include fEMG sensors disposed within and externally exposed at the gasket 106, so that they come into contact with the skin of the wearer 102's face 104 when the HMD 100 is worn by the wearer 102.

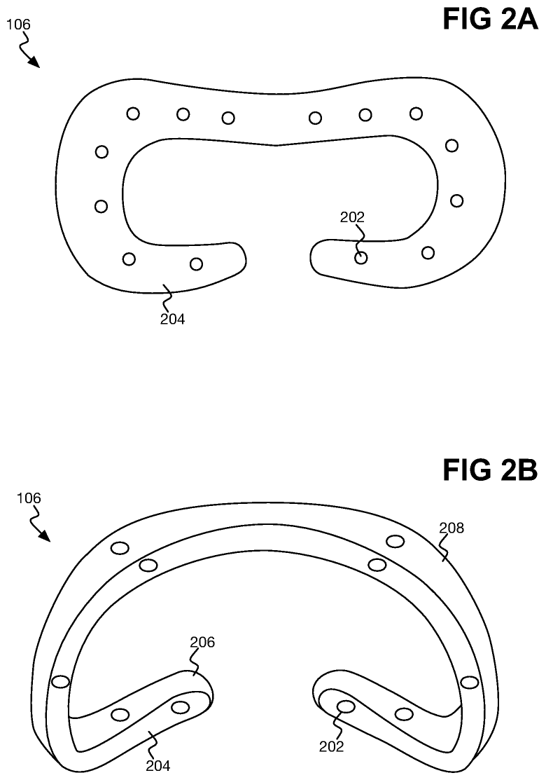

FIGS. 2A and 2B show front and perspective view diagrams, respectively, of different examples of the gasket 106 of the HMD 100 in detail. The gasket 106 includes an external surface 204 that comes into contact with the face 104 of the wearer 102 when the HMD 100 is worn by the wearer 102. FIGS. 2A and 2B show different examples of where resistive or magnetic sensors 202 of the HMD 100 can be disposed within the gasket 106. The number, orientation, and locations of the sensors 202 can differ from that shown in the figures.

In FIG. 2A, the resistive or magnetic sensors 202 are positioned along the external surface 204 of the gasket 106. However, the sensors 202 are internally disposed within the gasket 106 and not actually externally exposed at the external surface 204. FIG. 2A thus shows where the sensors 202 are located relative to the external surface 204, even though the sensors 202 are integrated within the gasket 106 and not externally visible in actuality.

In FIG. 2B, the resistive or magnetic sensors 202 are positioned along an inner external surface 206 and an outer external surface 208 of the gasket 106 in addition to the external surface 204. The inner external surface 206 is shielded from ambient light when the HMD 100 is worn by the wearer 102, whereas the outer external surface 206 remains exposed to ambient light when the wearer 102 is wearing the HMD 100. As in FIG. 2A, the sensors 202 are internally disposed within the gasket 106 and not externally exposed at any surface 204, 206, or 208, such that FIG. 2B shows where the sensors 202 are located relative to these external surfaces 204, 206, and 208, even though the sensors 202 are integrated within the gasket 106 and not externally visible in actuality.

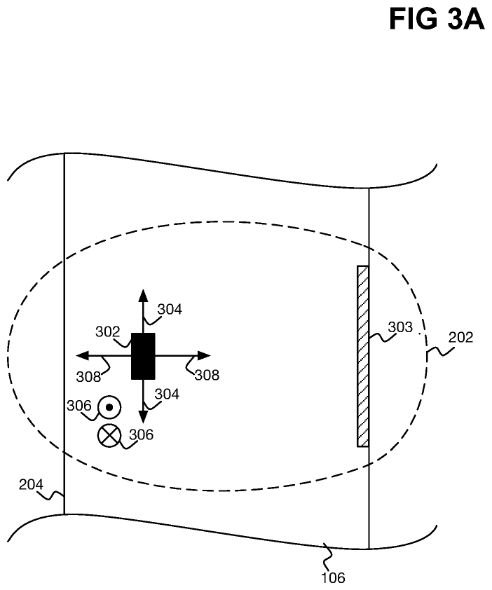

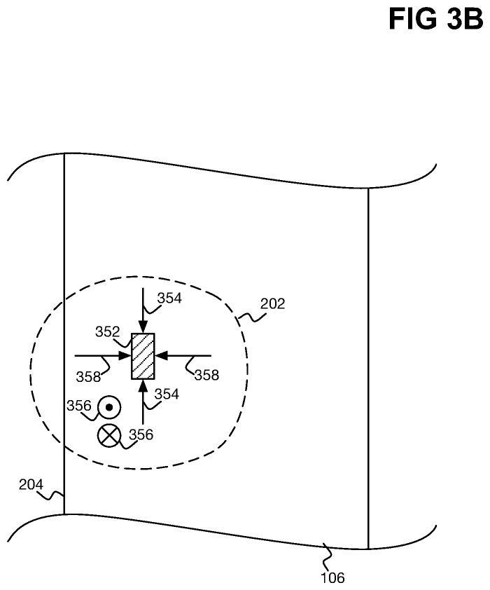

FIG. 3A shows an example sensor 202 disposed within the gasket 106 of the HMD 100 that is specifically a magnetic sensor. The magnetic sensor 202 is in particular a Hall effect sensor including a magnetic element 302 and a sensing element 303. The magnetic element 302 is disposed inside of the external surface 204 of the gasket 106 that comes into contact with the face 104 of the wearer 102 of the HMD 100. The sensing element 303 can be disposed at the opposite surface of the gasket 106.

The magnetic sensor 202 outputs sensor values corresponding to the physical displacement of the gasket 106 resulting from movement of the gasket 106 caused by facial movement of the wearer 102 that occurs as the wearer 102 exhibits facial expressions. The magnetic sensor 202 can be a three-axis sensor that measures such planar movement of the gasket 106 along its external surface 204, as well as axial movement perpendicular to the surface 204. The magnetic sensor 202 may instead just be a two-axis sensor that measures such planar movement of the gasket 106, or just a one-axis sensor that measures such axial movement of the gasket 106.

Specifically, as the wearer 102 exhibits facial expressions, the associated facial movement of the wearer 102 results in corresponding planar movement of the gasket 106 parallel to the external surface 204 against which the face 104 of the wearer 102 is positioned, and/or corresponding axial movement of the gasket 106 perpendicular to the surface 204. Such movement of the gasket 106 resultantly moves the magnetic element 302 relative to the sensing element 303. Such movement of the magnetic element 302 relative to the sensing element 303 causes a change in the magnetic field between the elements 302 and 303, which is why the sensor 202 is a magnetic sensor.

The magnetic element 302 may move vertically per the arrows 304, and/or into or out of the plane of the figure per the arrows 306, where the tail of the arrow 306 into the plane is depicted as an X inside a circle and the tip of the arrow 306 out of the plane is depicted as a dot inside a circle. The arrows 304 and 306 correspond to the axes that define the plane of the external surface 204 of the gasket 106, and therefore movement of the magnetic element 302 in the direction of the arrows 304 and/or 306 corresponds to planar movement of the gasket 106 along the surface 204. The magnetic element 302 may also move horizontally per the arrows 308, which correspond to the axis that is perpendicular to the plane of the surface 204. Therefore, movement of the magnetic element 302 in the direction of the arrows 308 corresponds to axial movement of the gasket 106 perpendicular to the external surface 204.

FIG. 3B shows an example sensor 202 disposed within the gasket 106 of the HMD 100 that is specifically a resistive sensor. The resistive sensor 202 is in particular a resistive strain gauge sensor including a strain gauge element 352. The strain gauge element 352 is disposed inside of the external surface 204 of the gasket 106 that comes into contact with the face of the wearer 102 of the HMD 100.

The resistive sensor 202 outputs sensor values corresponding to physical strain imparted on the gasket 106 resulting from movement of the gasket 106 caused by facial movement of the wearer 102 that occurs as the wearer 102 exhibits facial expressions. The resistive sensor 202 can be a three-axis sensor, such as a strain gauge sensor rosette, that effectively measures such planar movement of the gasket 106 along its external surface 204, as well as axial movement perpendicular to the surface 204. The resistive sensor 202 may instead be a two-axis sensor that measures such planar movement of the gasket 106, or just a one-axis sensor that measures such axial movement of the gasket 106.

Specifically, as the wearer 102 exhibits facial expressions, the associated facial movement of the wearer 102 results in corresponding planar movement of the gasket 106 parallel to the external surface 204 against which the face 104 of the wearer 102 is positioned, and/or corresponding axial movement of the gasket 106 perpendicular to the surface 204. Such movement of the gasket 106 resultantly imparts physical strain on the strain gauge element 352. Such physical strain on the strain gauge element 352 increases resistance of the element 302, which is why the sensor 202 is a resistive sensor.

The strain gauge element 352 may have physical strain imparted on it vertically per the arrows 354, or along directions into or out of the plane of the figure per the arrows 356, where the tail of the arrow 356 into the plane is depicted as an X inside a circle and the tip of the arrow 356 out of the plane is depicted as a dot inside a circle. The arrows 354 and 356 correspond to the axes that define the plane of the external surface 204 of the gasket 106, and therefore physical strain on the element 352 in the direction of the arrows 354 and 356 corresponds to planar movement of the gasket 106 along the surface 204. The strain gauge element 352 may also move horizontally per the arrows 358, which correspond to the axis that is perpendicular to the plane of the surface 204. Therefore, physical strain on the element 352 in the direction of the arrows 358 corresponds to axial movement of the gasket 106 perpendicular to the external surface 204.

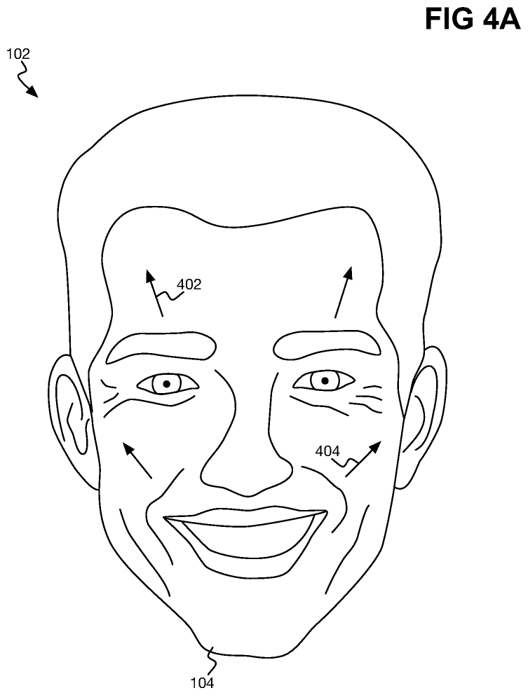

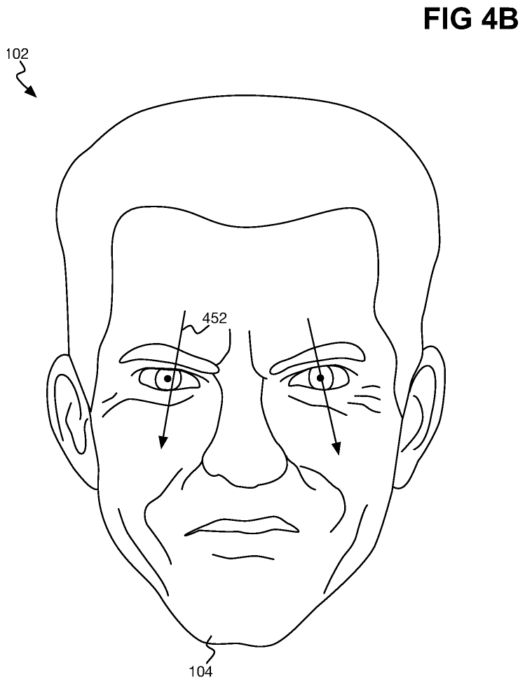

FIGS. 4A and 4B show the wearer 102 of the HMD 100 exhibiting different example facial expressions on his or her face 104. In FIG. 4A, the wearer 102 is exhibiting a facial expression of happiness, whereas in FIG. 4B the wearer 102 is exhibiting a facial expression of anger. FIGS. 4A and 4B specifically show how facial movement of the wearer 102 differs with different facial expressions.

In FIG. 4A, the eyebrows and forehead of the wearer 102 move upwards, per arrows 402, when exhibiting happiness. Similarly, the mouth corners and cheeks of the wearer 102 move upwards, per arrows 404, when exhibiting happiness. Such facial movement of the wearer 102 causes corresponding movement of the gasket 106 positioned against the wearer 102's face 104, per FIGS. 3A and 3B. Physical displacement is specifically measured if the sensors 202 are resistive sensors, per FIG. 3A, and physical strain is specifically measured if the sensors 202 are magnetic sensors, per FIG. 3B.

In FIG. 4B, by comparison, the eyebrows, cheeks, and mouth corners of the wearer 102 move downwards, per arrows 452, when exhibiting anger. Such facial movement of the wearer 102 also causes corresponding movement of the gasket 106 positioned against the wearer 102's face 104, per FIGS. 3A and 3B. As noted, physical displacement is specifically measured if the sensors 202 are resistive sensors, per FIG. 3A, and physical strain is specifically measured if the sensors 202 are magnetic sensors, per FIG. 3B.

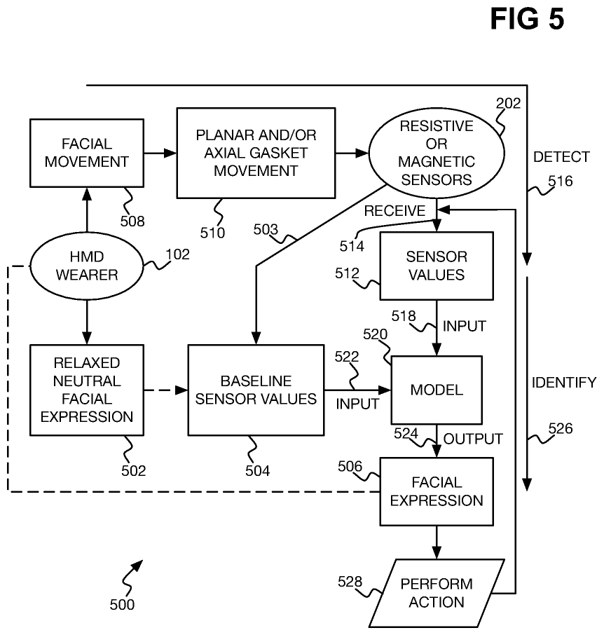

FIG. 5 shows an example process 500 for identifying the facial expression of the wearer 102 of an HMD 100 using resistive or magnetic sensors 202 disposed within the gasket 106 of the HMD 100. When the wearer 102 puts on the HMD 100 and is exhibiting a relaxed neutral facial expression 502, baseline sensor values 504 from the sensors 202 are received (503) and recorded. For example, the wearer 102 may be requested to exhibit a relaxed neutral facial expression, and upon the wearer 102 indicating that such a facial expression is being exhibited, the baseline sensor values 504 may be recorded. As another example, that the wearer 102 is exhibiting a relaxed neutral facial expression may be automatically detected, with the baseline sensor values 504 responsively recorded.

Thereafter, the wearer 102 can exhibit a facial expression 506 that correspondingly results in facial movement 508 of the wearer 102. Such wearer facial movement 508 in turn results in planar and/or axial movement 510 of the gasket 106, with sensor values 512 corresponding to physical strain or displacement accordingly received (514) from the resistive or magnetic sensors 202. In this way, then, the gasket movement 510 and thus the wearer facial movement 508 are detected (516).

In the example process 500, the sensor values 512 are input (518) into a model 520, as are (522) the baseline sensor values 504, with the model 524 resultantly outputting (i.e., predicting) (524) the facial expression 506 of the HMD wearer 102. The model 520 may be a machine learning model, for instance, which has been trained using resistive or magnetic sensor values labeled with corresponding facial expressions. The model 520 may be a statistical, algorithmic, or rules-based model instead of a machine learning model as well.

In this way, then, the wearer 102's facial expression 506 is identified based on the received sensor values 512 (526). The sensor values 512 correspond to physical strain on or displacement of the gasket 106 as the wearer 102 is currently exhibiting the facial expression 506 as compared to the baseline sensor values 504, which correspond to the physical strain on or displacement when the wearer is exhibiting the relaxed neutral facial expression 502. Therefore, in the example process 500, the baseline sensor values 504 effectively serve to calibrate the model 524 in predicting and thus identifying the current facial expression 506 of the wearer 102.

An action can then be performed (528) based on the identified facial expression 506 of the wearer 102. For instance, an avatar representing the wearer 102 may be rendered to have the same facial expression 506, and displayed. As another example, further biometric inference processing may be performed using the identified facial expression 506, such as to deduce facial cues and the mood or emotion of the wearer.

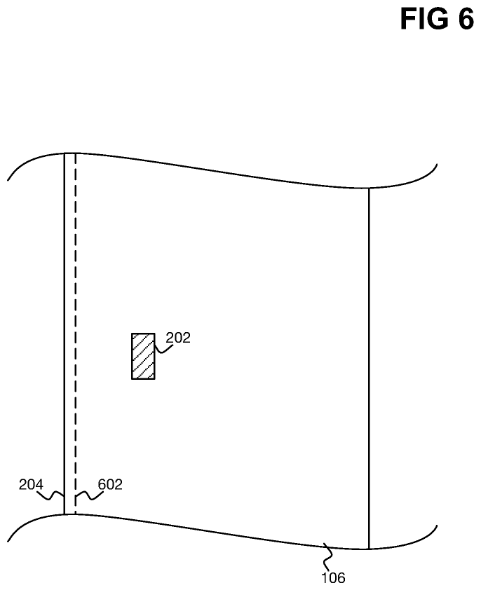

FIG. 6 shows an example as to how a resistive or magnetic sensor 202 disposed within the gasket 106 of the HMD 100 can be used to detect proper fit of the HMD 100 to the wearer 102. The HMD 100 should be securely mounted to the wearer 102, and not be too loose so as to potentially result in the HMD 100 slipping while being worn, which can affect the XR experience of the wearer 102. However, the HMD 100 should not be too tight so as to cause undue discomfort on the wearer 102.

As depicted in the figure, when the HMD 100 is properly fitted to the wearer 102, the external surface 204 of the gasket 106 that is positioned against the face 104 of the wearer 102 should as an example compress to position 602. If the HMD 100 is fitted too loosely, then the surface 204 may not fully compress to the position 602. Similarly, if the HMD 100 is fitted too tightly, then the surface 204 may compress past the position 602.

The resistive or magnetic sensor 202 can thus be used to detect proper fitment of the HMD 100 to the wearer 102. If the sensor 202 detects strain or displacement that is (within a fit threshold) less than that corresponding to the position 602, then the HMD 100 may be too loose. By comparison, if the sensor 202 detects strain or displacement that is (within the fit threshold) greater than that corresponding to the position 602, then the HMD 100 may be too tight. The wearer 102 may thus be notified to correspondingly tighten or loosen the HMD 100 to ensure proper fit.

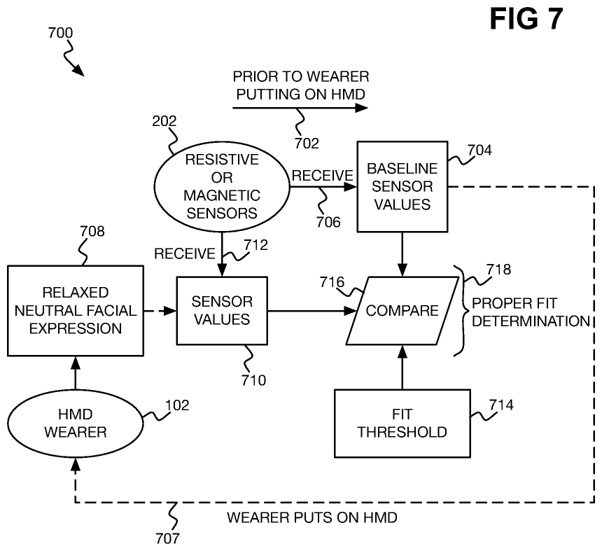

FIG. 7 shows an example process 700 for determining whether the HMD 100 has been properly fitted to the wearer 102 using resistive or magnetic sensors 202 disposed within the gasket 106 of the HMD 100. Prior to the wearer 102 putting on the HMD 100 (702), baseline sensor values 704 are received (706) from the sensors 202. Once the HMD wearer 102 puts on the HMD 100 (707) and is exhibiting a relaxed neutral facial expression (708), additional sensor values 710 are also received (712) from the sensors 202. The sensor values 710 can thus be compared (716) to the baseline sensor values 704 to determine whether the HMD 100 is properly fitted to the wearer 102 within a fit threshold 714 (718).

The baseline sensor values 704 specifically correspond to strain or displacement when the external surface 204 of the gasket 106 is in a position when the HMD 100 is not being worn. The sensor values 710 correspond to strain or displacement when the surface 204 is positioned against the face 104 of the wearer 102 when exhibiting a relaxed neutral facial expression 708. Because the sensor values 710 effectively measure movement of the gasket 106, including along the axial direction perpendicular to the external surface 204 of the gasket 106, the sensor values 710 relative to the baseline sensor values 704 are indicative of whether the surface 204 has compressed to within the fit threshold 714 of the position 602 corresponding to proper HMD fitment. In this way, proper fitment can be determined.

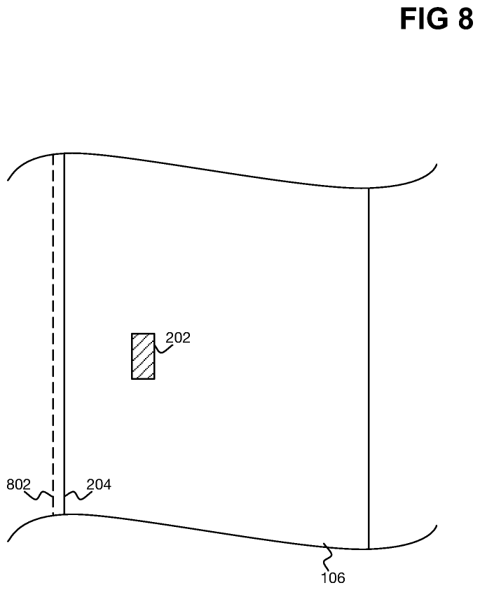

FIG. 8 shows an example as to how a resistive or magnetic sensor 202 disposed within the gasket 106 of the HMD 100 can be used to detect excessive wear of the gasket 106. As noted, the gasket 106 can be fabricated from a soft flexible material, such as rubberized foam. Over time, the resilience and/or flexibility of the gasket 106 may degrade, and/or the gasket 106 may start to decompose. Such excessive gasket wear can impact the XR experience of the wearer 102, preventing the HMD 100 from remaining securely positioned against the wearer 102 even if initially properly fitted.

As depicted in the figure, when the HMD 100 is new, such as at manufacture or otherwise prior to first use of the HMD 100, the external surface 204 of the gasket 106 may initially have a default position 802. Over time, the surface 204 may remain compressed in its current position as shown in FIG. 8 even when not being worn. For example, frequent usage of the HMD 100, combined with the decomposition or degrading resiliency or flexibility of the gasket 106, may result in the gasket 106 being unable to revert back to the position 802 when the HMD 100 is no longer being worn.

The resistive or magnetic sensor 202 can thus be used to detect excessive wear of the gasket 106 of the HMD 100. If when the wearer 102 is not wearing the HMD 100 (i.e., before the wearer 102 puts on the HMD 100) the sensor 202 detects strain or displacement that is more than a wear threshold greater than that corresponding to the position 802, then the gasket 106 may have excessively worn. The wearer 102 may thus be notified to replace the gasket 106.

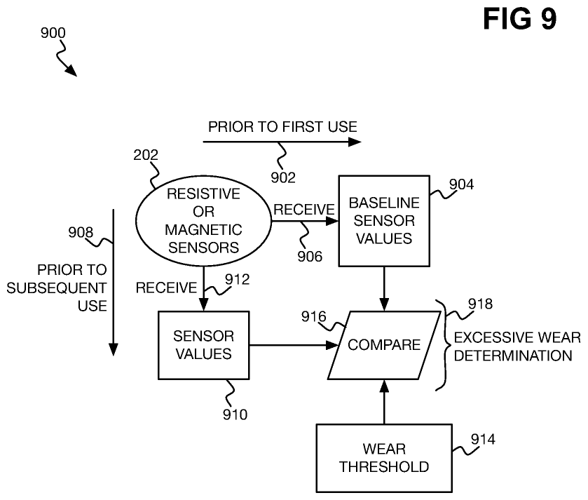

FIG. 9 shows an example process 900 for determining whether the gasket 106 of the HMD 100 has become excessively worn using resistive or magnetic sensors 202 disposed within the gasket 106. Prior to first use of the HMD 100 (902), baseline sensor values 904 are received (906) from the sensors 202. Prior to each subsequent use (i.e., before the wearer 102 puts on the HMD 100) (908), additional sensor values 910 are also received (912) from the sensors 902. The sensor values 910 can thus be compared (916) to the baseline sensor values 904 to determine whether the gasket 106 has become worn by more than a wear threshold 914 (918).

The baseline sensor values 904 specifically correspond to strain or displacement when the external surface 204 of the gasket 106 is in the default position 802 prior to first use of the HMD 100. The sensor values 910 correspond to subsequent strain or displacement when the HMD 100 is not being worn, such as when the surface 204 remains compressed and does not revert to the default position 802 after removal. Because the sensor values 910 effectively measure movement of the gasket 106, including along the axial direction perpendicular to the external surface 204 of the gasket 106, the sensor values 910 relative to the baseline sensor values 904 are indicative of whether the surface 204 has compressed by more than the wear threshold 914 from the default position 802. In this way, excessive gasket wear can be determined.

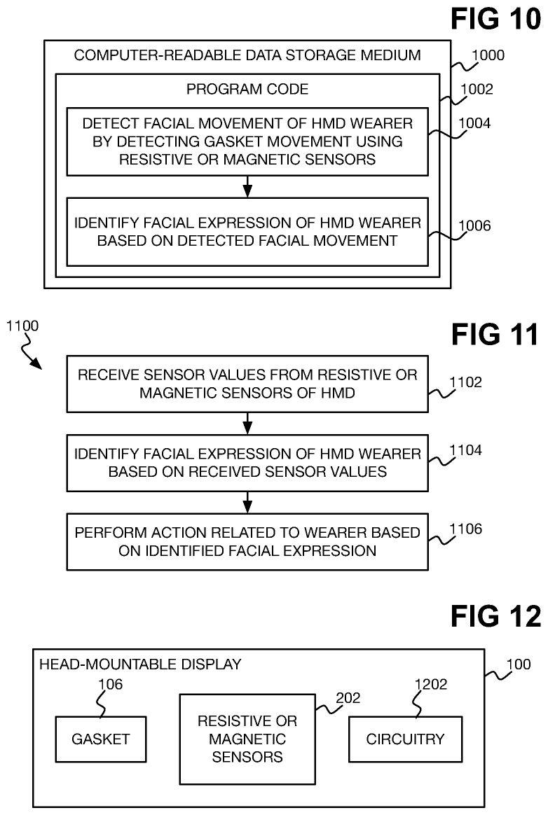

FIG. 10 shows an example non-transitory computer-readable data storage medium 1000 that stores program code 1002 executable by a processor to perform processing. The processing includes detecting facial movement 508 of the wearer 102 of the HMD 100 by detecting movement 510 of the gasket 106 of the HMD 100 positioned against the face 104 of the wearer 102, using resistive or magnetic sensors 202 within the gasket 106 (1004). The processing further includes identifying the facial expression 506 of the wearer 102 based on the detected facial movement 508 (1006).

The processor that executes the program code 1002 may be part of a host device, such as a computing device like a computer, smartphone, and so on, to which the HMD 100 is communicatively connected. The processor may instead be part of the HMD 100 itself. The processor and the data storage medium 1000 may be integrated within an application-specific integrated circuit (ASIC) in the case in which the processor is a special-purpose processor. The processor may instead be a general-purpose processor, such as a central processing unit (CPU), in which case the data storage medium 1000 may be discrete from the processor. The processor and/or the data storage medium 1000 may constitute circuitry.

FIG. 11 shows an example method 1100. The method 1100 may be performed by a processor, such as that of the HMD 100 or a host device to which the HMD 100 is communicatively connected. The method 1100 may be implemented as program code stored on a non-transitory computer-readable data storage medium. In such instance, the processor and the data storage medium may be integrated within an ASIC or be discrete from one another, as noted above, and may together constitute circuitry.

The method 1100 includes receiving sensor values 512 from resistive or magnetic sensors 202 within the gasket 106 of the HMD 100 positioned against the face 104 of the wearer 102 of the HMD 100, as the wearer is exhibiting a facial expression 506 (1102). The method 1100 includes identifying the facial expression 506 of the wearer 102 based on the received sensor values 512 (1104). The method 1100 includes performing an action related to the wearer 102 based on the identified facial expression 506 of the wearer 102 (1106).

FIG. 12 shows a block diagram of the example HMD 100. The HMD 100 includes a gasket 106 positionable against the face 104 of the wearer 102. The HMD 100 includes resistive or magnetic sensors 202 within the gasket 106 to detect movement 510 of the gasket 106 responsive to facial movement 508 of the wearer 102 while the wearer is exhibiting a facial expression 506. The HMD 100 can include circuitry 1202 to identify the facial expression 506 of the wearer 102 based on the detected movement 510 of the gasket 106.

Techniques have been described herein for using resistive or magnetic sensors 202 within the gasket 106 of an HMD 100 for identifying the facial expression 506 of the wearer 102 of the HMD 100. The sensors 202 can be resistive sensors, such as physical strain gauge sensors that measure physical strain, or can be magnetic sensors, such as Hall effect sensors that measure physical displacement. In either case, the sensors 202 effectively measure movement 510 of the gasket 106 resulting from facial movement 508 of the wearer 102 while exhibiting a facial expression 506, and thus effectively measure such facial movement 508 of the wearer 102 of the HMD 100. The facial expression 506 of the wearer 102 can then be identified from the sensor values 512 received from the sensors 202.

We claim:

1. A non-transitory computer-readable data storage medium storing program code executable by a processor to perform processing comprising:
detecting facial movement of a wearer of a head-mountable display (HMD) by detecting movement of a gasket of the HMD positioned against a face of the wearer using a plurality of resistive or magnetic sensors within the gasket; and
identifying a facial expression of the wearer based on the detected facial movement.

2. The non-transitory computer-readable data storage medium of claim 1, wherein the processing further comprises:
performing an action related to the wearer of the HMD based on the identified facial expression of the wearer.

3. The non-transitory computer-readable data storage medium of claim 1, wherein detecting the movement of the gasket of the HMD using the plurality of resistive or magnetic sensors comprises:
detecting planar movement of the gasket along an external surface of the gasket in contact with the face of the wearer.

4. The non-transitory computer-readable data storage medium of claim 3, wherein detecting the movement of the gasket of the HMD using the plurality of resistive or magnetic sensors further comprises:
detecting axial movement of the gasket perpendicular to the external surface of the gasket in contact with the face of the wearer.

5. The non-transitory computer-readable data storage medium of claim 1, wherein the resistive or magnetic sensors are resistive strain gauge sensors, and wherein detecting the movement of the gasket of the HMD comprises:
receiving sensor values from the resistive strain gauge sensors corresponding to physical strain on the gasket as the wearer is currently exhibiting the facial expression as compared to baseline sensor values corresponding to the physical strain on the gasket when the wearer is exhibiting a relaxed neutral facial expression,
wherein the facial expression of the wearer is determined based on the received sensor values.

6. The non-transitory computer-readable data storage medium of claim 1, wherein the resistive or magnetic sensors are magnetic Hall effect sensors, and wherein detecting the movement of the gasket of the HMD comprises:
receiving sensor values from the magnetic Hall effect sensors corresponding to physical displacement of the gasket as the wearer is currently exhibiting the facial expression as compared to baseline sensor values corresponding to the physical displacement of the gasket when the wearer is exhibiting a relaxed neutral facial expression,
wherein the facial expression of the wearer is determined based on the received sensor values.

7. The non-transitory computer-readable data storage medium of claim 1, wherein the processing further comprises:
receiving sensor values from the resistive or magnetic sensors when the wearer is exhibiting a relaxed neutral facial expression; and
determining whether the HMD is properly fitted to the wearer within a threshold by comparing the sensor values to baseline sensor values before the wearer put on the HMD.

8. The non-transitory computer-readable data storage medium of claim 1, wherein the processing further comprises:
receiving sensor values from the resistive or magnetic sensors before the wearer put on the HMD; and
determining whether the gasket of the HMD has become worn by more than a threshold by comparing the sensor values to baseline sensor values prior to first use of the HMD.

9. A method comprising:
receiving, by a processor, sensor values from a plurality of resistive or magnetic sensors within a gasket of a head-mountable display (HMD) positioned against a face of a wearer of the HMD, as the wearer is exhibiting a facial expression;
identifying, by the processor, the facial expression of the wearer based on the received sensor values; and
performing, by the processor, an action related to the wearer based on the identified facial expression of the wearer.

10. The method of claim 9, wherein the resistive or magnetic sensors are resistive strain gauge sensors, and the sensor values are indicative of physical strain on the gasket resulting from movement of the gasket as the wearer is exhibiting the facial expression.

11. The method of claim 9, wherein the resistive or magnetic sensors comprise magnetic Hall effect sensors, and the sensor values are indicative of physical displacement of the gasket resulting from movement of the gasket as the wearer is exhibiting the facial expression.

12. A head-mountable display (HMD) comprising:
a gasket positionable against a face of a wearer; and
a plurality of resistive or magnetic sensors within the gasket to detect movement of the gasket responsive to facial movement of the wearer while the wearer is exhibiting a facial expression.

13. The HMD of claim 12, further comprising:
circuitry to identify the facial expression of the wearer based on the detected movement of the gasket.

14. The HMD of claim 12, wherein the resistive or magnetic sensors comprise resistive strain gauge sensors that measure physical strain on the gasket resulting from the movement of the gasket responsive to the facial movement of the wearer.

15. The HMD of claim 12, wherein the resistive or magnetic sensors comprise magnetic Hall effect sensors that measure physical displacement of the gasket resulting from the movement of the gasket responsive to the facial movement of the wearer.
